(19) United States
(12) Patent Application Publication
(10) Pub. No.: US 2021/0119491 A1
(43) Pub. Date: Apr. 22, 2021

(54) Wireless Charger with Microwave Transformed Power and Energy-Storing

(71) Applicants: Ching Wu Wang, Kaohsiung (TW); Solar Master Energy Co., Ltd., New Taipei (TW); Anji Technology Co., Ltd., Tainan (TW)

(72) Inventors: Ching Wu Wang, Kaohsiung (TW); Cheng Ju Li, Taoyuan (TW); Yi Li Chen, Changhua (TW); Chun Sheng Chen, Taoyuan (TW)

(73) Assignees: Ching Wu Wang; Solar Master Energy Co., Ltd.; Anji Technology Co., Ltd.

(21) Appl. No.: 16/725,772

(22) Filed: Dec. 23, 2019

(30) Foreign Application Priority Data
Oct. 21, 2019 (TW) 108137944

(51) Int. Cl. H02J 50/27; H02J 50/12; H03H 7/38

(52) U.S. Cl. CPC H02J 50/27; H02J 50/005; H03H 7/38; H02J 50/12

(57) ABSTRACT

A wireless charger for charging an electric device includes an emitting device and a receiving device. The emitting device generates microwaves and the receiving device receives the microwaves from the emitting device and transforms the microwaves into electrical power. The receiving device includes a receiving antenna receiving the microwaves from the emitting device, an impedance matching circuit electrically connected to the receiving antenna, a voltage doubler rectifier filter circuit electrically connected to the impedance matching circuit, and a boost module electrically connected to the voltage doubler rectifier filter circuit. The receiving antenna has a small signal reflection and a small power loss in receiving the microwaves; the impedance matching circuit works with the voltage doubler rectifier filter circuit to provide a small power loss when the microwaves are transformed into the electrical power to directly or indirectly charge the electric device with a high voltage.

### BACKGROUND OF THE INVENTION

### 1. Technical Field

The present invention relates to wireless charging, and more particularly to a wireless charger with power transformed from microwave.

### 2. Description of Related Art

Typically, a common specification of a conventional wireless charger in the present market is Qi, which is an open interface standard that defines wireless power transfer using inductive charging over a short distance, developed by Wireless Power Consortium (WPC). The Qi provides cell phones and other electric devices to be wireless charged. Such a wireless charger includes a charging board, a cable and a plug. The plug is connected to a power source to supply the charging board with necessary power, and then an electric device may be put on the charging board to be charged. It is easy to understand that the charging board is energized through the cable and the plug, so that the charging board must be placed nearby the power source. Besides, the mobile device must be put on the charging board that is another limitation of the conventional wireless charger.

There are many improved wireless chargers, providing a power charger with power transformed from light, infrared ray, and laser. Such a charger will not charge anything unless it is exposed under light.

Another conventional wireless charger disclosed a wireless charger and a charging method, which is energized by microwave. The mobile device will not be charged unless a router of the charger received a request from the mobile device.

Another conventional wireless charger disclosed a microwave charging system, including a microwave generator, a microwave charger, and a charging device. The system transforms microwaves to mechanical power, and then transforms the mechanical power to electrical power. It will have a lot of loss in energy convention.

Another conventional provided a microwave charging system, including a microwave/DC transforming and charge controlling module. This module provides a high-frequency transformer to be a rectifier circuit in low-power microwave condition, and a bridge rectifier and a zener diode in parallel for clamp in high-power microwave condition. This system provides two different rectifier circuits for rectification in high and low power microwave conditions without teaching how the rectifier circuits are switched. Besides, this patent taught that the output power of DC is 85% under a circumstance of a low-frequency voltage doubler rectifier circuit with a good impedance matching and a filter. However, no disclosure for what kind of impedance match is to achieve the proposed power output.

### BRIEF SUMMARY OF THE INVENTION

In view of the above, the primary objective of the present invention is to provide a wireless charger, which may transform microwaves into electrical power and store the electrical power for charging.

In order to achieve the objective of the present invention, a wireless charger for charging an electric device includes an emitting device for emitting microwaves and a receiving device connected to the electric device to receive the microwaves from the emitting device and transform the microwaves into electrical power. The receiving device includes a receiving antenna receiving the microwaves from the emitting device, an impedance matching circuit electrically connected to the receiving antenna, a voltage doubler rectifier filter circuit electrically connected to the impedance matching circuit, and a boost module electrically connected to the voltage doubler rectifier filter circuit.

The receiving antenna has a small signal reflection and a small power loss in receiving the microwaves; the impedance matching circuit works with the voltage doubler rectifier filter circuit to provide a small power loss when the microwaves are transformed into the electrical power to directly or indirectly charge the electric device with a high voltage.

The present invention further provides a receiving device of a wireless charger, which is intended to connect an electric device to charge the electric device, including a receiving antenna for receiving microwaves; an impedance matching circuit electrically connected to the receiving antenna; a voltage doubler rectifier filter circuit electrically connected to the impedance matching circuit; and a boost module electrically connected to the voltage doubler rectifier filter circuit.

With the wireless charger of the present invention, it may fix the prior arts with inefficient power transformation and communication control problem. The present invention provides an efficient way to transform microwaves into electrical power without extra communication control to provide user a convenient way of charging and save the resource.

### BRIEF DESCRIPTION OF THE SEVERAL VIEWS OF THE DRAWINGS

The present invention will be best understood by referring to the following detailed description of some illustrative embodiments in conjunction with the accompanying drawings, in which

FIG. 1 is a sketch diagram of a first preferred embodiment of the present invention;

FIG. 2 is a block diagram of the emitting device of the first preferred embodiment of the present invention;

FIG. 3 is a block diagram of the receiving device of the first preferred embodiment of the present invention;

FIG. 4 is a Smith chart of the receiving antenna of the first preferred embodiment of the present invention;

FIG. 5 is a reflection loss chart of the receiving antenna of the first preferred embodiment of the present invention;

FIG. 6 is a block diagram of the receiving device of a second preferred embodiment of the present invention;

FIG. 7 is a circuit of the voltage doubler rectifier filter circuit of the second preferred embodiment of the present invention;

FIG. 8 is another circuit of the voltage doubler rectifier filter circuit of the second preferred embodiment of the present invention;

FIG. 9 is the other circuit of the voltage doubler rectifier filter circuit of the second preferred embodiment of the present invention; and

FIG. 10 is a block diagram of a third preferred embodiment of the present invention, showing the receiving device having the multiple electrical connectors.

### DETAILED DESCRIPTION OF THE INVENTION

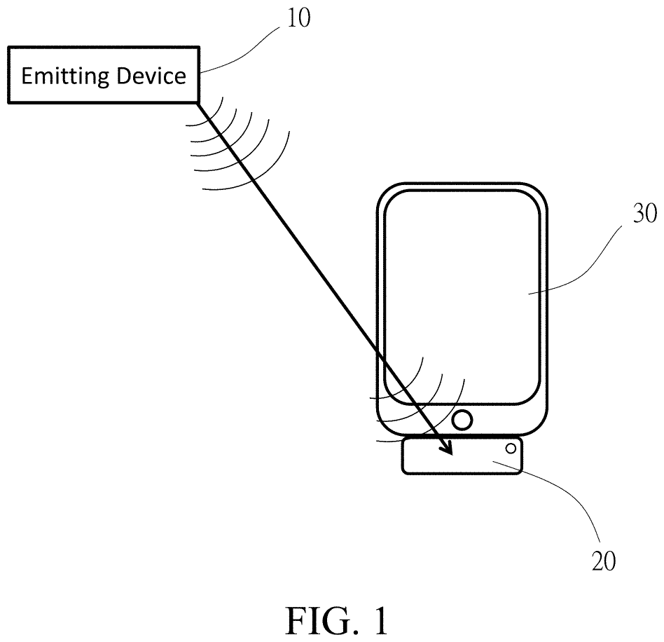

As shown in FIG. 1, a wireless system of the first preferred embodiment of the present invention includes an emitting device 10, a receiving device 20, and an electric device 30 to be charged. The emitting device 10 provides microwaves with a predetermined frequency and a predetermined power, and the receiving device 20 receives the microwaves from the emitting device 10 and transforms the microwaves into electrical power. The electric device 30 is connected to the receiving device 20 to be charged by the electrical power generated by the receiving device 20. The receiving device 20 may be an external device related to the electric device 30, or the receiving device 20 is installed in the electric device 30.

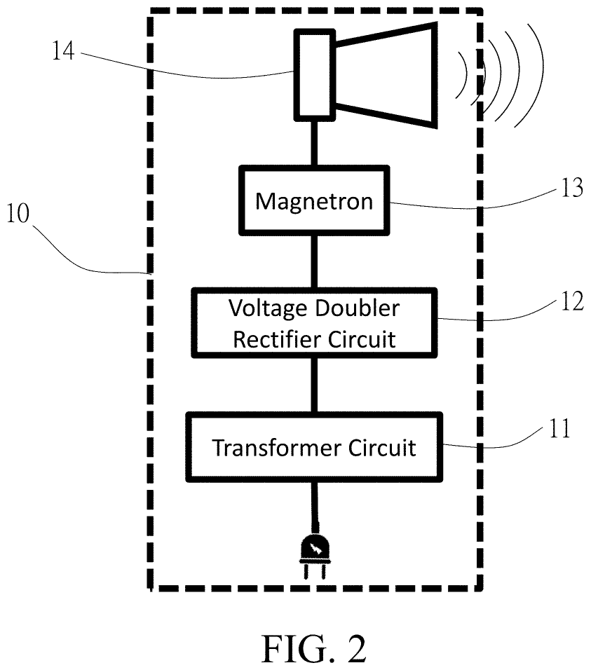

As shown in FIG. 2, the emitting device 10 has a transformer circuit 11, a voltage doubler rectifier circuit 12, a magnetron 13, and a directing member 14. The transformer circuit 11 is electrically connected to a plug (not shown) to be connected to an external power source (not shown) for supplying the emitting device 10 with electrical power. The voltage doubler rectifier circuit 12 is electrically connected to the transformer circuit 11 for voltage double rectification of the electrical power from the transformer circuit 11. The magnetron 13 receives the electrical power from voltage doubler rectifier circuit 12 to generate microwaves with a predetermined frequency and a predetermined power. The directing member 14 is connected to the magnetron 13 to emit the microwaves in a predetermined direction. In an embodiment, the directing member 14 has a horn-like output terminal to direct an emitting direction of the microwaves.

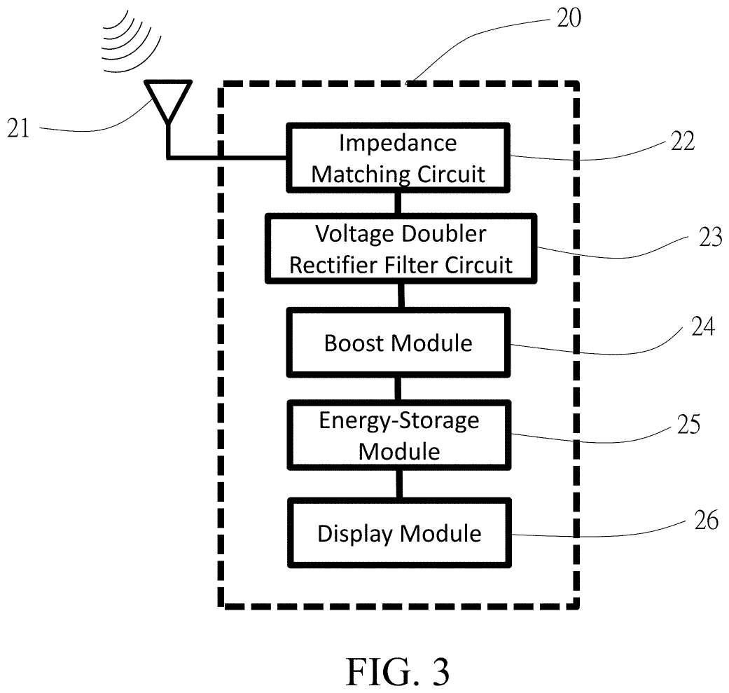

As shown in FIG. 3, the receiving device 20 includes a receiving antenna 21, an impedance matching circuit 22, a voltage doubler rectifier filter circuit 23, a boost module 24, an energy-storage module 25, and a display module 26.

The receiving antenna 21 may be a dipole antenna, a printed circuit antenna, or other equivalent microwave receiving antennas. A number of the receiving antenna 21 may be more than one according to the requirement, such as two, three, or more. The impedance matching circuit 22 is electrically connected to the receiving antenna 21. The impedance matching circuit 22 may be a L-match impedance matching circuit, a T-match impedance matching circuit, or a π-match impedance matching circuit, wherein the π impedance matching circuit connected to an inductance in parallel is preferable.

The voltage doubler rectifier filter circuit 23 is electrically connected to the impedance matching circuit 22. The voltage doubler rectifier filter circuit 23 has a plurality of capacities, diodes, and other electric elements electrically connected in a predetermined pattern. The boost module 24 is electrically connected to the voltage doubler rectifier filter circuit 23 to increase the output voltage of the voltage doubler rectifier filter circuit 23.

The energy-storage module 25 may have a rechargeable battery and/or a capacity. The energy-storage module 25 is electrically connected to the boost module 24 to store the electrical power from the boost module 24. The display module, which is a LED screen or a liquid crystal screen, is electrically connected to the energy-storage module 25 to show a quantity of the stored power of the energy-storage module 25 and a condition of the energy-storage module 25, such as charging or discharging.

As shown in FIGS. 1 to 3, the microwaves generated by the emitting device 10 is received by the receiving antenna 21 of the receiving device 20, and then is processed by the impedance matching circuit 22 and the voltage doubler rectifier filter circuit 23 to output an electrical power with a predetermined voltage. Next, the voltage of the electrical power is increased by the boost module 24 to charge the electric device 30 through the energy-storage module 25 or charge the energy-storage module 25.

With the emitting device 10 and the receiving device 20 as described above, the inventor carried out a test for the performance of transforming microwaves into electrical power. The frequency of the microwaves generated by the emitting device 10 is set to 2.45 GHz, and a length of the receiving antenna 21 is set to an integer multiple of a wavelength of half-wave of the microwaves.

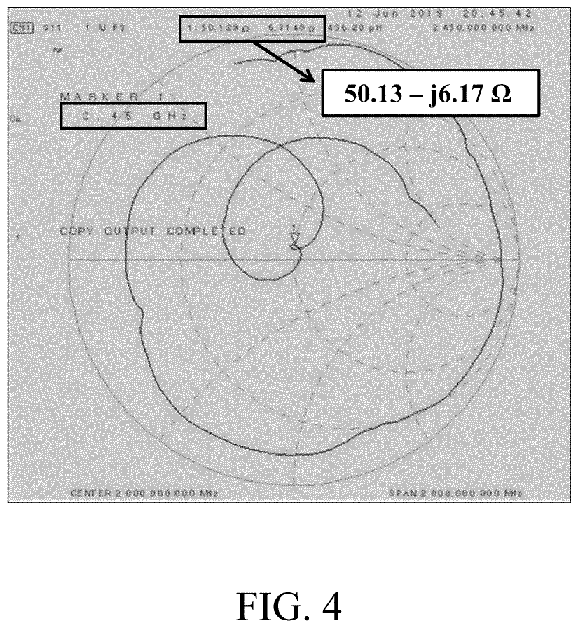

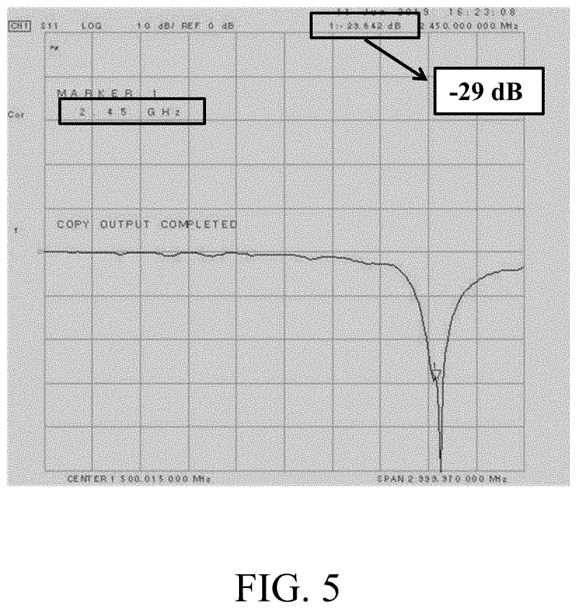

FIG. 4 is a Smith chart of the test, showing a matching impedance of the receiving antenna 21 receiving 2.45 GHz microwaves is 50.13−j6.17Ω, which is very close to a resistance of a cable (50Ω). FIG. 5 is a reflection loss chart, showing the reflection loss of the receiving antenna 21 receiving 2.45 GHz microwaves is −29 dB, and a ratio of reflection loss is 0.125%.

Table 1 shows the data of transforming 8 W microwaves into electrical power under different distance between the emitting device 10 and the receiving device 20.

TABLE 1

| Distance | Voltage | Current | Power | Intensity | Load Resistance |
|---|---|---|---|---|---|
| (cm) | (mV) | (mA) | (□W) | (W/m²) | (Ω) |
| 20 | 87 | 0.087 | 7.6 | 1.705 | 1000 |
| 30 | 72 | 0.071 | 5.2 | 0.833 | 1000 |
| 40 | 66 | 0.067 | 4.4 | 0.814 | 1000 |
| 50 | 53 | 0.053 | 2.8 | 0.246 | 1000 |

According to the result of the test, the wireless charger of the present embodiment of the present invention may have a very small signal reflection and power loss when the receiving device 20 received the microwaves and the microwaves may be transformed into electrical power with predetermined voltage and current in a predetermined distance. Basing on the result, it may further infer that the wireless charger of the present embodiment of the present invention may have a longer charging distance and generate electrical power with larger voltage and current by providing higher power microwaves.

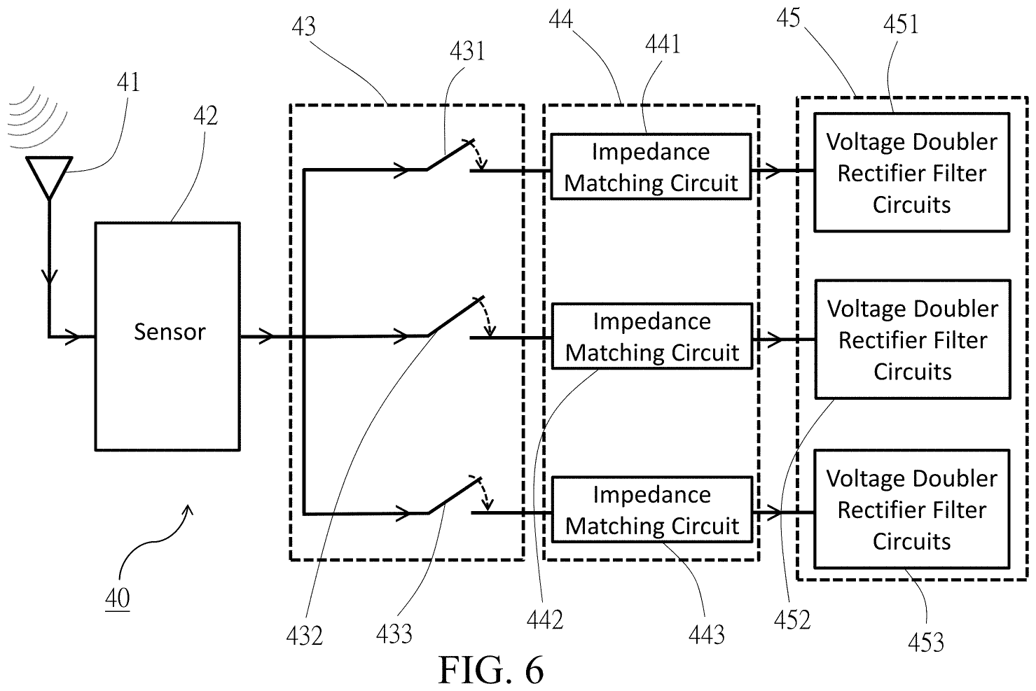

As shown in FIG. 6, the second preferred embodiment of the present invention provides a receiving device 40, having one or more receiving antennas 41, a sensor 42, a switch module 43, an impedance matching circuit module 44, and a voltage doubler rectifier filter circuit module 45.

The sensor 42 is electrically connected to the receiving antennas 41. The sensor 42 is a Hall effect sensor for sensing the intensity of electromagnetic waves in a range between 0 and 20 W/m².

The switch module 43 is electrically connected to the sensor 42. The switch module 43 has three switches 431, 432 and 433. The impedance matching circuit module 44 has three impedance matching circuits 441, 442 and 443. The voltage doubler rectifier filter circuit module 45 has three voltage doubler rectifier filter circuits 451, 452 and 453.

The switches 431, 432 and 433 are electrically connected in parallel. The switch 431, the impedance matching circuit 441 and the voltage doubler rectifier filter circuit 451 are electrically connected in series. The switch 432, the impedance matching circuit 442 and the voltage doubler rectifier filter circuit 452 are electrically connected in series. The switch 433, the impedance matching circuit 443 and the voltage doubler rectifier filter circuit 453 are electrically connected in series.

The switches 431, 432 and 433 of the switch module 43 are respectively turned on or off according to an intensity of the microwaves sensed by the sensor 42. For example, the switch 431 is turned on and the rest two switches 432 and 433 are turned off when the intensity of the microwaves sensed by the sensor 42 is between 0 and 5 W/m², so that the microwaves are processed by the impedance matching circuit 441 and the voltage doubler rectifier filter circuit 451 in sequence. The switch 432 is turned on and the rest two switches 431 and 433 are turned off when the intensity of the microwaves sensed by the sensor 42 is between 5 and 12 W/m², so that the microwaves are processed by the impedance matching circuit 442 and the voltage doubler rectifier filter circuit 452 in sequence. The switch 433 is turned on and the rest two switches 431 and 432 are turned off when the intensity of the microwaves sensed by the sensor 42 greater than 12 W/m², so that the microwaves are processed by the impedance matching circuit 443 and the voltage doubler rectifier filter circuit 453 in sequence.

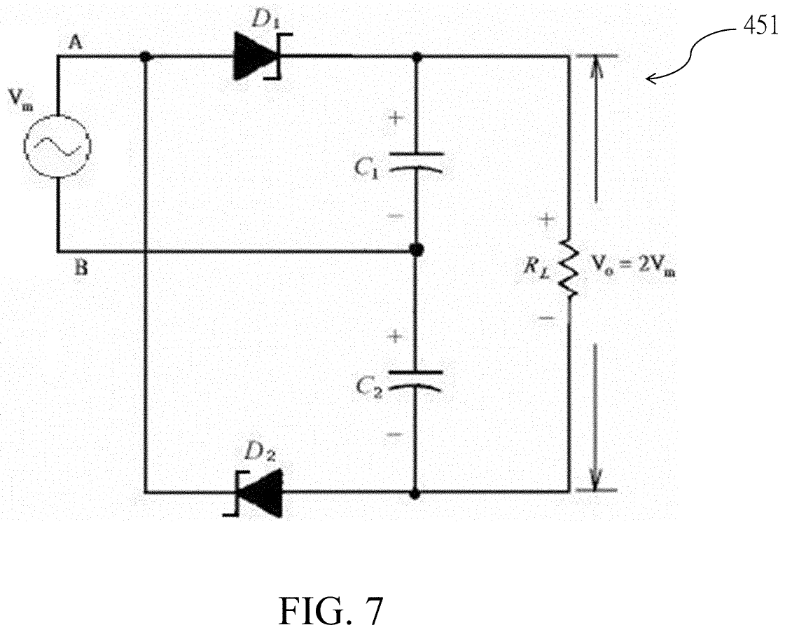

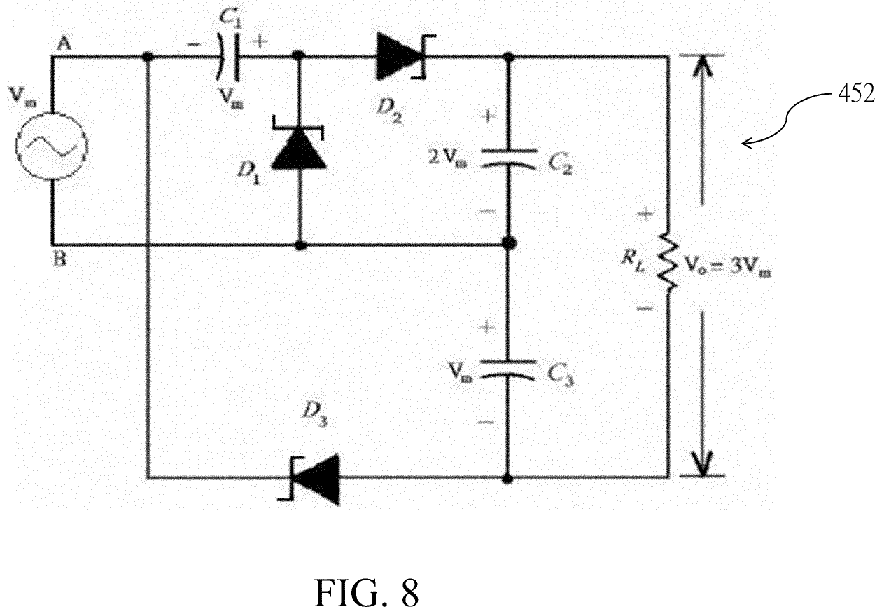

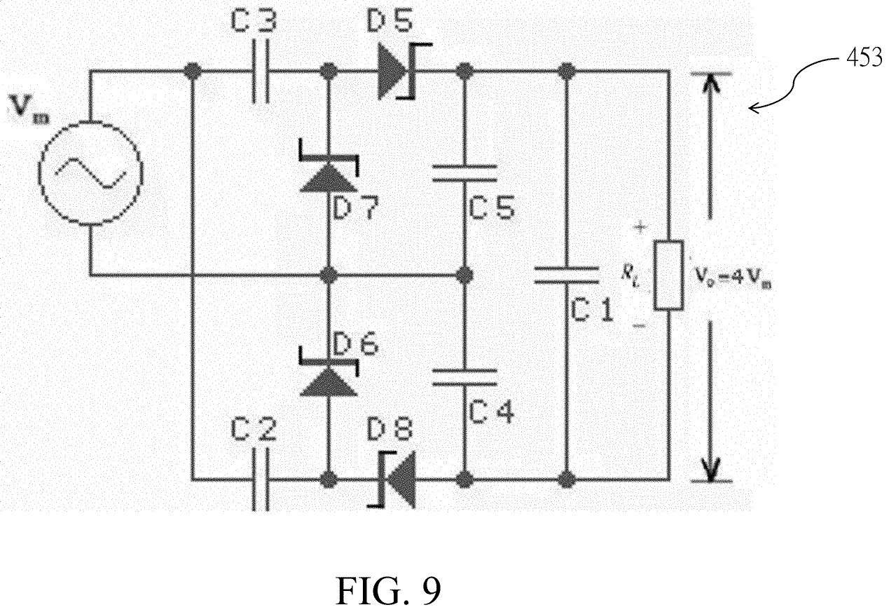

FIG. 7 shows a circuit of the voltage doubler rectifier filter circuit 451. FIG. 8 shows another circuit of the voltage doubler rectifier filter circuit 452. FIG. 9 shows the other circuit of the voltage doubler rectifier filter circuit 453.

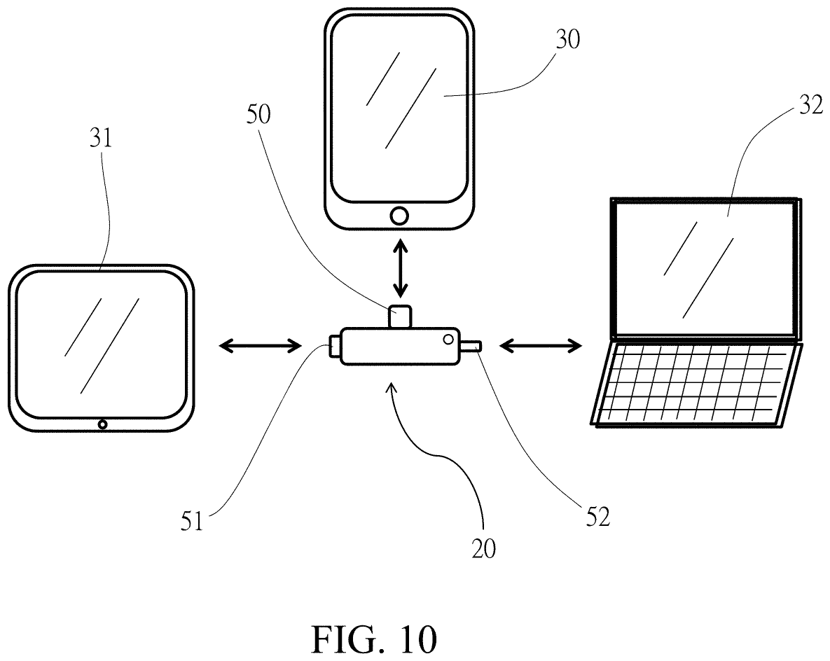

As shown in FIG. 10, the third preferred embodiment of the present invention provides a receiving device 20 having a plurality of electrical connectors 50, 51 and 52 for different electric devices 31, 32 and 33 to be charged. For example, the electrical connectors 50, 51 and 52 may be micro-USB, USB Type-C, and lightening to charge various electric devices.

In conclusion, the present invention provides a wireless charger to transform microwaves into electrical power for charging electric devices. The receiving device may be electrically connected to the electric device or directly installed inside the electric device, so that the electric device is able to be charged in a predetermined range of the emitting device to achieve the real “wireless” charging. In practice, the emitting device may be installed at a specified place, such as living room, station, airport, library, and park. As long as a person carries an electric device with the receiving device and enters the range of the emitting device, the electric device will be charged automatically.

It must be pointed out that the embodiments described above are only some preferred embodiments of the present invention. All equivalent structures which employ the concepts disclosed in this specification and the appended claims should fall within the scope of the present invention.

What is claimed is:

1. A wireless charger for charging an electric device, comprising:
an emitting device for emitting microwaves; and
a receiving device connected to the electric device to receive the microwaves from the emitting device and transform the microwaves into electrical power; the receiving device including a receiving antenna receiving the microwaves from the emitting device, an impedance matching circuit electrically connected to the receiving antenna, a voltage doubler rectifier filter circuit electrically connected to the impedance matching circuit, and a boost module electrically connected to the voltage doubler rectifier filter circuit;
Wherein the receiving antenna has a small signal reflection and a small power loss in receiving the microwaves; the impedance matching circuit works with the voltage doubler rectifier filter circuit to provide a small power loss when the microwaves are transformed into the electrical power to directly or indirectly charge the electric device with a high voltage.

2. The wireless charger of claim 1, wherein the impedance matching circuit includes a π impedance matching circuit and an inductance connected in parallel.

3. The wireless charger of claim 1, wherein the voltage doubler rectifier filter circuit includes a plurality of capacities and diodes electrically connected in a predetermined pattern.

4. The wireless charger of claim 1, wherein the receiving device further includes a sensor and a switch module; the sensor senses an intensity of the microwaves from the emitting device; the switch module includes two switches; the receiving device further includes a impedance matching circuit and a voltage doubler rectifier filter circuit; one of the switches, one of the impedance matching circuits and one of the voltage doubler rectifier filter circuits are connected in series while the other switch, the other impedance matching circuits and the other voltage doubler rectifier filter circuits are disconnected; the switches are turned on or off according to the intensity of the microwaves sensed by the sensor.

5. The wireless charger of claim 1, wherein the emitting device includes has a transformer circuit, a voltage doubler rectifier circuit, and a magnetron connected in series; the voltage doubler rectifier circuit provides electrical power to the magnetron, and the magnetron generates the microwaves accordingly.

6. The wireless charger of claim 5, wherein the emitting device further includes a directing member receiving the microwaves from the magnetron to guide an emitting direction of the microwaves.

7. The wireless charger of claim 1, wherein the receiving device further includes a energy-storage module and a display module, and the energy-storage module is electrically connected to the boost module.

8. The wireless charger of claim 1, wherein the receiving device further includes an electrical connector to socket the electric device to be charged.

9. The wireless charger of claim 1, wherein the receiving antenna of the receiving device includes a dipole antenna.

10. The wireless charger of claim 1, wherein a length of the receiving antenna is an integer multiple of a wavelength of half-wave of the microwaves.

11. A receiving device of a wireless charger, which is intended to connect an electric device to charge the electric device, comprising:
a receiving antenna for receiving microwaves;
an impedance matching circuit electrically connected to the receiving antenna;
a voltage doubler rectifier filter circuit electrically connected to the impedance matching circuit; and
a boost module electrically connected to the voltage doubler rectifier filter circuit;
wherein the receiving antenna has a small signal reflection and a small power loss in receiving the microwaves; the impedance matching circuit works with the voltage doubler rectifier filter circuit to provide a small power loss when the microwaves are transformed into the electrical power to directly or indirectly charge the electric device with a high voltage.

12. The receiving device of the wireless charger of claim 11, wherein the impedance matching circuit includes a π impedance matching circuit and an inductance connected in parallel.

13. The receiving device of the wireless charger of claim 11, wherein the voltage doubler rectifier filter circuit includes a plurality of capacities and diodes electrically connected in a predetermined pattern.

14. The receiving device of the wireless charger of claim 11, further comprising a sensor, a switch module, a impedance matching circuit and a voltage doubler rectifier filter circuit; wherein the sensor senses an intensity of the microwaves; the switch module includes two switches; one of the switches, one of the impedance matching circuits and one of the voltage doubler rectifier filter circuits are connected in series while the other switches, the other impedance matching circuits and the other voltage doubler rectifier filter circuits are disconnected; the switches are turned on or off according to the intensity of the microwaves sensed by the sensor.

15. The receiving device of the wireless charger of claim 11, wherein further comprising an energy-storage module and a display module, wherein the energy-storage module is electrically connected to the boost module.

16. The receiving device of the charger of claim 11, wherein further comprising an electrical connector to socket the electric device to be charged.

17. The receiving device of the wireless charger of claim 11, wherein the receiving antenna includes a dipole antenna.

18. The receiving device of the wireless charger of claim 11, wherein a length of the receiving antenna is an integer multiple of a wavelength of half-wave of the microwaves.
